(19) United States
(12) Patent Application Publication
(10) Pub. No.: US 2025/0218819 A1
(43) Pub. Date: Jul. 3, 2025

(54) RADIATIVE HEAT WINDOWS AND WAFER SUPPORT PADS IN VAPOR ETCH REACTORS

(71) Applicant: Lam Research Corporation, Fremont, CA (US)

(72) Inventors: Ilia Kalinovski, Berkeley, CA (US); David S. L. Mui, Fremont, CA (US); Gnanamani Amburose, Fremont, CA (US); Butch Berney, Pleasanton, CA (US); Mark Naoshi Kawaguchi, San Carlos, CA (US); Bryan Michael Cord, San Jose, CA (US); Venkata Sharat Chandra Parimi, Sunnyvale, CA (US)

(21) Appl. No.: 18/848,895

(22) PCT Filed: Mar. 29, 2023
(86) PCT No.: PCT/US2023/016762

§ 371 Date: Sep. 19, 2024

Related U.S. Application Data
(60) Provisional application No. 63/362,327, filed on Mar. 31, 2022.
(60) Provisional application No. 63/362,329, filed on Mar. 31, 2022.

(51) Int. Cl. H01L 21/67; H01L 21/3065; H01L 21/687

(52) U.S. Cl. CPC H01L 21/67115; H01L 21/3065; H01L 21/67069; H01L 21/67248; H01L 21/6875; H01L 21/68757

(57) ABSTRACT

An apparatus may include: (a) a processing chamber including chamber walls and a chamber heater configured to heat the chamber walls; and (b) a pedestal positioned within the chamber interior and including: (i) a substrate heater having a plurality of light emitting diodes (LEDs), (ii) a window positioned above the substrate heater comprising a material transparent to light from the LEDs, and (iii) three or more substrate support pads, each substrate support, pad having a substrate support surface vertically offset from the window and configured to support a substrate such that the window and the substrate supported by the three or more substrate support pads are offset by a nonzero distance.

### INCORPORATION BY REFERENCE

A PCT Request From is filed concurrently with this specification as part of the present application. Each application that the present application claims benefit of or priority to as identified in the concurrently filed PCT Request From is incorporated by reference herein in their entireties and for all purposes.

### BACKGROUND

Semiconductor fabrication sometimes involve patterning schemes and other processes in which some regions on a substrate surface are selectively etched. Other fabrication processes employ deposition of materials on a substrate surface. In either case, variations over the face of the substrate in process conditions or in incoming substrates may need to be addressed. As device geometries become smaller, uniformity control has become more important.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Aspects of this disclosure pertain to apparatus for semiconductor processing, which apparatus may be characterized by the following features: (a) a processing chamber including chamber walls that at least partially bound a chamber interior, and a chamber heater configured to heat the chamber walls; and (b) a pedestal positioned within the chamber interior and including: (i) a substrate heater having a plurality of light emitting diodes (LEDs), (ii) a window positioned above the substrate heater comprising a material transparent to light from the LEDs, wherein the window comprises sapphire, spinel, AlON, IR grade fused silica, or a fluoride of an alkaline earth element, and (iii) three or more substrate support pads, each substrate support pad having a substrate support surface vertically offset from the window and configured to support a substrate such that the window and the substrate supported by the three or more substrate support pads are offset by a nonzero distance.

In certain embodiments, the window has thickness of about 5 to 40 mm. In certain embodiments, the window has a diameter of about 250-500 mm. In certain embodiments, a top surface of the window is nonplanar, and/or a bottom surface of the window is nonplanar. In certain embodiments, the window comprises sapphire.

In certain embodiments, the pedestal further includes a sidewall, and an outer region of the window is thermally connected to the sidewall such that heat can be transferred between the outer region and the sidewall.

In certain embodiments, the pedestal includes a bowl in which the substrate heater is positioned, and the bowl includes one or more sidewalls having an exterior surface that comprises reflective material.

In certain embodiments, the pedestal additionally includes a pedestal cooler that is thermally connected to the LEDs such that heat can be transferred between the LEDs and the pedestal cooler. The pedestal cooler may also include at least one fluid channel within the pedestal, and/or be configured to flow a cooling fluid within the at least one fluid channel. In some implementations, the pedestal further includes a pedestal heater configured to heat one or more exterior surfaces of the pedestal.

In certain embodiments, a first set of LEDs are arranged in a first circle having a first radius around a center axis of the substrate heater, and equally spaced apart from each other, and a second set of LEDs are arranged in a second circle having a second radius larger than the first radius around the center axis, and equally spaced apart from each other.

In certain embodiments, a first set of LEDs are electrically connected to form a first electrical zone, a second set of LEDs are electrically connected to form a second electrical zone, and the first and second electrical zones are independently controllable.

In certain embodiments, the apparatus additionally includes a pyrometer having a detector connected to a port and sensor window through a fiberoptic cable. In some implementations, the pyrometer is configured to detect emissions having one or more wavelengths of about 1 to about 4 microns.

In certain embodiments, the apparatus additionally includes (i) a gas distribution unit including: one or more fluid inlets, and a faceplate having a plurality of through-holes fluidically connected to the one or more fluid inlets and to the chamber interior and having a front surface partially bounding the chamber interior; and (ii) a unit heater thermally connected to the faceplate such that heat can be transferred between the faceplate and the unit heater.

Any combination of the above features may be implemented together in apparatus aspects of this disclosure.

Aspects of this disclosure pertain to methods that may be characterized by the following operations: (a) supporting a substrate in a processing chamber having chamber walls using a pedestal having a plurality of substrate support pads that each contact an edge region of the substrate; (b) heating, while the substrate is supported by only the plurality of substrate supports, the substrate to a first temperature by emitting visible light from a plurality of light emitting diodes (LEDs) under the substrate through a window comprising sapphire, spinel, AlON, IR grade fused silica, or a fluoride of an alkaline earth element; and (c) etching, while the substrate is supported by only the plurality of substrate supports and while the substrate is at the first temperature, a surface of the substrate. Any combination of these operations may be implemented using any features of the apparatus aspects of this disclosure.

Aspects of this disclosure pertain to apparatus for semiconductor processing, which apparatus may be characterized by the following features: a processing chamber including chamber walls that at least partially bound a chamber interior, and a chamber heater configured to heat the chamber walls, and a pedestal positioned within the chamber interior. The pedestal may include: (i) a substrate heater having a plurality of light emitting diodes (LEDs), (ii) a window positioned above the substrate heater comprising a material transparent to light from the LEDs, and (iii) three or more substrate support pads, each substrate support pad having a substrate support surface vertically offset from the window and configured to support a substrate such that the window and the substrate supported by the three or more substrate support pads are offset by a nonzero distance, wherein the substrate support pads comprise zirconia or quartz.

In certain embodiments, each substrate support comprises a zirconia. In certain embodiments, each substrate support includes a temperature sensor configured to detect a temperature of a substrate positioned on the substrate support surface. In certain embodiments, a top surface of the window is nonplanar, and/or a bottom surface of the window is nonplanar. In certain embodiments, the substrate support pads comprise yttria-stabilized zirconia.

In certain embodiments, the pedestal further includes a sidewall, and an outer region of the window is thermally connected to the sidewall such that heat can be transferred between the outer region and the sidewall.

In certain embodiments, the pedestal includes a bowl in which the substrate heater is positioned, and the bowl includes one or more sidewalls having an exterior surface that comprises reflective material.

In certain embodiments, the pedestal additionally includes a pedestal cooler that is thermally connected to the LEDs such that heat can be transferred between the LEDs and the pedestal cooler. The pedestal cooler may include at least one fluid channel within the pedestal, and/or be configured to flow a cooling fluid within the at least one fluid channel. In some implementations, the pedestal further includes a pedestal heater configured to heat one or more exterior surfaces of the pedestal.

In certain embodiments, the apparatus includes a first set of LEDs are arranged in a first circle having a first radius around a center axis of the substrate heater, and equally spaced apart from each other, and a second set of LEDs are arranged in a second circle having a second radius larger than the first radius around the center axis, and equally spaced apart from each other.

In certain embodiments, the apparatus includes a first set of LEDs are electrically connected to form a first electrical zone, a second set of LEDs are electrically connected to form a second electrical zone, where the first and second electrical zones are independently controllable.

In certain embodiments, the apparatus includes a pyrometer having a detector connected to the port and sensor window through a fiberoptic cable. The pyrometer may be configured to detect emissions having one or more wavelengths of about 1 to about 4 microns.

In certain embodiments, the apparatus additionally includes:
a gas distribution unit including:
one or more fluid inlets, and
a faceplate having a plurality of through-holes fluidically connected to the one or more fluid inlets and to the chamber interior, and having a front surface partially bounding the chamber interior; and
a unit heater thermally connected to the faceplate such that heat can be transferred between the faceplate and the unit heater.

Any combination of the above features may be implemented together in apparatus with the recited substrate support pads.

Aspects of this disclosure pertain to methods that may be characterized by the following operations: (a) supporting a substrate in a processing chamber having chamber walls using only a pedestal having a plurality of substrate support pads that each contact an edge region of the substrate, wherein the substrate support pads comprise zirconia or quartz; (b) heating, while the substrate is supported by only the plurality of substrate supports, the substrate to a first temperature by emitting visible light from a plurality of light emitting diodes (LEDs) under the substrate; and (c) etching, while the substrate is supported by only the plurality of substrate supports and while the substrate is at the first temperature, a surface of the substrate. Any combination of these operations may be implemented using any features of the apparatus aspects of this disclosure.

These and other features of the disclosure will be presented in more detail below, and in some cases, with reference to the associated drawings.

### BRIEF DESCRIPTION OF THE DRAWINGS

FIG. 1 depicts a cross-sectional side view of an example apparatus in accordance with disclosed embodiments.

FIG. 2 depicts a top view of a substrate heater with a plurality LEDs.

FIG. 3 depicts a top view of another substrate heater with a plurality LEDs.

FIG. 4 depicts the pedestal of FIG. 1 with additional features in accordance with various embodiments.

FIG. 5 depicts the pedestal of FIG. 4 with additional features in accordance with various embodiments.

FIG. 6 depicts a substrate support of FIGS. 1 and 4 in accordance with disclosed embodiments.

FIG. 7 depicts a plan view of first example faceplate.

FIG. 8 depicts a plan view of second example faceplate.

FIG. 9 shows the differences in the abilities of quartz and sapphire windows to reach steady temperature and follow temperature changes when exposed to thermal cycling.

FIG. 10A illustrates a mechanism of pyrometry and how a window can interfere with that mechanism.

FIG. 10B illustrates the disparate effect of heating and cooling on a quartz window's emissions and pyrometry readings. FIG. 10C illustrates that a sapphire window's emissions do not similarly complicate pyrometry readings.

FIG. 10C illustrates that a sapphire window's emissions do not similarly complicate pyrometry readings.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

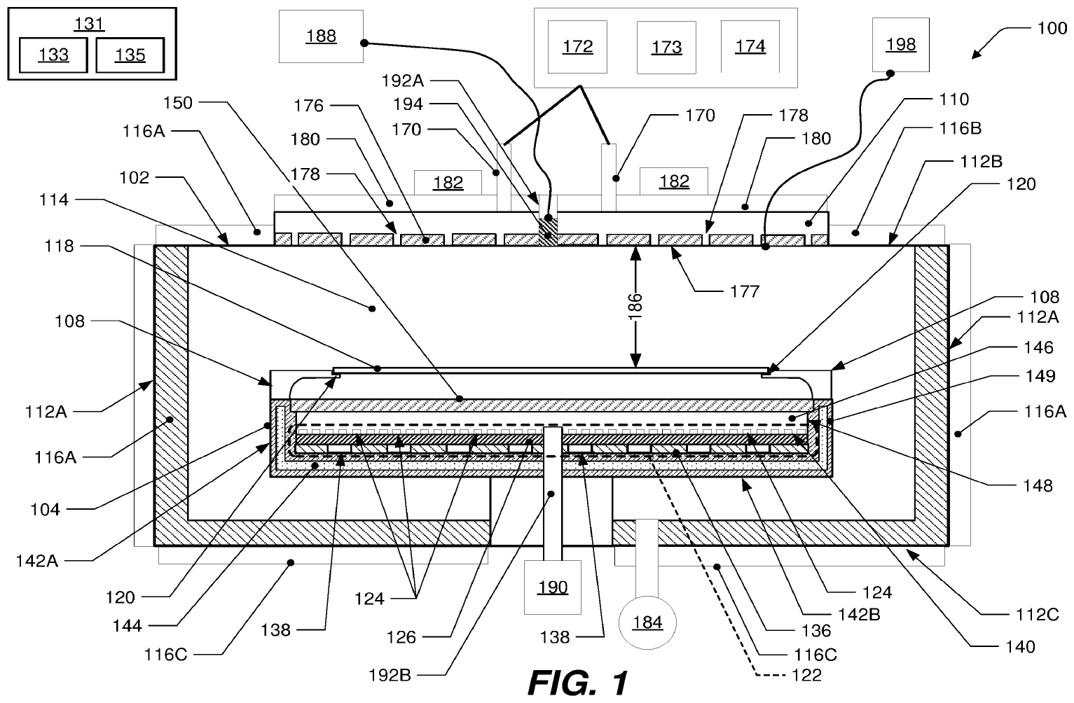

Some semiconductor fabrication processes require careful control of the local temperature of the substrate, over the face of the substrate. In some implementations, temperature control is achieved using a reactor that employs a plurality of heating elements that provide radiant energy to different regions the substrate. Further information about such reactors and the processes they support is provided below. See e.g., FIGS. 1-8. Any aspects of the windows, support pads, or contacts described herein may be used in conjunction with such reactors and processes. One example of such reactor is the Prevos™, which employs many LEDs to locally heat regions on the face of the substrate. The Prevos™ is available from Lam Research of Fremont, CA.

In some embodiments, apparatuses for conducting semiconductor device fabrication processes that require temperature control employ a window disposed between radiative heat sources (e.g., a plurality of LEDs) and a substrate. Such windows may have multiple functions such as protecting radiative sources from damage caused by aggressive environments around the substrate. In some embodiments, the window separates an atmospheric side of the processing chamber, where the radiative heat source resides, from the vacuum side of the chamber, where the heated substrate is undergoing etch or other process by reactive vapor. During operation, the radiation that heats the substrate passes through the window.

In accordance with some embodiments of this disclosure, a window may have the following features: (1) transparency for the visible radiation emitted by the heat source for substrate heating; (2) little thermal crosstalk between window and wafer; and (3) resistance to attack by the process environment such as an aggressive etchant gas.

The inventors have identified materials that satisfy these requirements and therefore is used as a window material. Examples of such materials include optical grade sapphire (crystalline Al₂O₃), AlON, and spinel (MgAl₂O₄).

Quartz has also been used as window material. However, quartz windows have been observed to develop a “haze” over their lifetimes. The haze causes the window to become less effective in transferring power from the radiative heat source to the wafer. A cause of haze is etching of the quartz surface by aggressive process environments such as vapor etch chemistry. The material on the side of the window that contacts the vapor etch chemistry is continuously consumed. Possibly due to etch micro masking effects, the quartz surface, which is being etched develops micro roughness, which manifests as a haze. The haze can absorb and scatter light that passes through it. If the degradation of optical properties of the window is left uncompensated, the on-wafer temperature, and consequently the etch rate, will drift over the lifetime of the quartz window. Eventually, the haze becomes so severe that the window reaches the end of its service life and needs to be replaced.

Additionally, quartz windows may heat up as wafers run through a process tool, and the not window retains its high temperature for a long time after the process ends. This results in undesirable wafer-to-wafer process variation. It may also limit the throughput for high and low temperature cycling recipes. This is due to three physical properties of quartz. The first one is the extremely low heat conductivity of quartz. The second one is the low material strength of quartz, which requires that windows be relatively thick, thereby increasing their thermal mass. And the third one is the high absorptivity of quartz in the infrared spectral range, where a heated substrate emits most of its thermal radiation. Quartz windows therefore retain significant heat at the end of the heating cycle, they absorb more heat at faster rate during the process, and they are inefficient in channeling and dissipating this retained heat after the process is over.

Further, hot quartz windows have high temperature non-uniformity over their surfaces, which may cause within wafer temperature non-uniformity and ultimately within wafer etch rate non-uniformity. This is partly due quartz windows having low thermal conductivity, high thermal mass, and high absorptivity.

Still further, hot quartz is a source of thermal radiation which can confound the measurement of wafer temperature by a radiative pyrometer. To avoid damage by the etch chemistry the pyrometer may be located on the atmospheric side of a window. Thus, when viewing the substrate, the pyrometer receives thermal emission of the window as well as the substrate. Thermal emission of the window is high because it is hot and because the quartz emissivity at a pyrometer's infrared wavelength is high.

By comparison to quartz, other materials such as sapphire (Al₂O₃) have a beneficial combination of mechanical, thermal, optical, and chemical properties. As a result, windows made from such materials overcome the above problems of quartz windows. Windows fabricated with sapphire are significantly less prone to developing haze problem and have a longer lifetime than quartz windows.

Sapphire has a considerably higher mechanical strength than quartz (flexure strength is greater by greater than 11 times), which allows a thinner (e.g., 3 times thinner) window design. The thermal conductivity of sapphire is about 30 times greater than quartz. Furthermore, sapphire absorbs less IR than quartz.

Certain other materials also compare favorably to quartz as window materials. These include AlON, calcium fluoride, and spinel (MgAl₂O₄).

In some embodiments, apparatuses for conducting semiconductor device fabrication processes that require temperature control employ support contacts for holding a substrate in position while the process takes place. Such contacts may be positioned to contact the substrate at multiple locations around its perimeter. These contacts sometimes take the form of fingers, pads, or tabs that extend inwardly from a ring or other structure, disposed outside the substrate perimeter, toward the substrate. During processing, the substrate rests on these pads.

These support pads may be constructed from many different materials. Examples of such materials include aluminum, including anodized aluminum, quartz, and zirconia, including yttria-stabilized zirconia.

In some disclosed embodiments, support pads impart (1) little or no perturbation to a substrate's temperature through heat conduction and/or blockage of thermal energy to the via, e.g., LED light, and (2) chemical resistance of support pad material toward the aggressive reactor conditions (e.g., etchant gas).

Hard-anodized aluminum has excellent chemical compatibility with certain vapor etch chemistries, and the anodization protects the interior bulk aluminum from the aggressive chemistry of the reactor. However, it has been observed that, when used in support pads, the heat conductivity of aluminum metal can produce wafer temperature uniformity, which translates into process non-uniformity such as etch rate non-uniformity.

In some embodiments, the support pads comprise zirconia (ZrO₂) or yttria-stabilized zirconia. In some cases, such material may be a ceramic. As a material for support pads, zirconia provides a useful combination of mechanical, thermal, and chemical properties. Its high mechanical strength enables fabrication of long parts with small cross-sections, at least by comparison to aluminum alloys. Furthermore, by comparison to aluminum and quartz, zirconia can provide a small contact area with the substrate. Further, the relatively low heat conductivity of zirconia, allows support pads to provide good thermal uniformity on the substrate. Still further, zirconia's chemical properties enable long service life of these parts, without degradation, in the aggressive environment of, e.g., a selective vapor etch reactor.

Support pads fabricated from quartz (SiO₂) provide an alternative implementation. Quartz has very low heat conductivity, and hence enables comparable thermal performance to zirconia. However, quartz is more likely to be etched in some environments. Therefore, quartz support pads may be consumable parts. Given the relatively low cost of quartz, this is acceptable for some applications. The periodic replacement of support pads may not have a large negative impact to the cost of ownership.

The support pads may have many different sizes and shapes. Some designs leverage the advantages of zirconia and/or quartz. Such designs may have relatively small contact areas with the substrate, fingers that are relatively long, and/or fingers that have a relatively large cross-section (in the direction of potential heat transfer).

### Apparatuses for Thermal Processing

Provided herein are methods and apparatuses for semiconductor processing, for example to etch a semiconductor substrate using thermal energy, rather than, or in addition to, plasma energy. In certain embodiments, etching that relies upon chemical reactions in conjunction with primarily thermal energy, not a plasma, to drive the chemical reactions may be considered “thermal etching”. In various embodiments, apparatuses described herein are designed or configured to rapidly heat and cool a substrate, and precisely control a substrate's temperature. In some embodiments, the substrate is rapidly heated and its temperature is precisely controlled using, in part, visible light emitted from light emitting diodes (LEDs) positioned in a pedestal under the substrate. The visible light may have wavelengths that include and range of about 400 nanometers (nm) to 800 nm. The pedestal may include various features for enabling substrate temperature control, such as a transparent window that optionally has lensing for directing or focusing the emitted light, reflective material also for directing or focusing the emitted light, and/or temperature control elements that assist with temperature control of the LEDs, the pedestal, and the chamber.

Such apparatuses are sometimes implemented as selective vapor etch reactors, such as the Lam Research Prevos™. Such reactors are used to fabricate advanced logic devices. For example, they are used in the IC fabrication industry's transition from finFET to gate all around (GAA) transistor devices. They are also used to fabricate 3D DRAM devices. In such reactors, a substrate such as a silicon wafer under process is immersed in a reactive gas environment, while being heated from below by a multi-source LED heater. The LED heater allows fast, accurate, and controllable temperature ramp up and ramp down cycles, thus making possible precise, atomic level control of etch reactions.

In some embodiments, the apparatuses herein thermally isolate, or thermally “float,” the substrate within the processing chamber so that only the smallest thermal mass is heated, the ideal smallest thermal mass being just the substrate itself, which enables fast heating and cooling. The substrate may be rapidly cooled using a cooling gas and/or radiative heat transfer to a heat sink, such as a top plate (or other gas distribution element) above the substrate, or both. In some instances, the apparatus also includes temperature control elements within the processing chamber walls, pedestal, and top plate (or other gas distribution element), to enable further temperature control of the substrate and processing conditions within the chamber, such as prevention of unwanted condensation of processing gases and vapors.

The apparatuses may also be configured to implement various control loops to precisely control the substrate and the chamber temperatures (e.g., with a controller configured to execute instructions that cause the apparatus to perform these loops). This may include the use of various sensors that determine substrate and chamber temperatures as part of open loops and feedback control loops. These sensors may include temperature sensors in the substrate supports which contact the substrate and measure its temperature, and non-contact sensors such as photodetectors to measure light output of the LEDs and a pyrometer configured to measure the temperature of different types of substrates. As described in more detail below, some pyrometers determine an item's temperature by measuring emitted infrared light or other optical signals from the item. However, many silicon substrates cannot be measured by some pyrometers because the silicon can be optically transparent at various temperatures and with various treatments, e.g., doped or low doped silicon. For example, a low doped silicon substrate at a temperature less than about, e.g., 300° C. is transparent to infrared signals. Certain pyrometers provided herein are able to measure multiple types of silicon substrates at various temperatures.

FIG. 1 presents a cross-sectional side view of an example apparatus in accordance with disclosed embodiments. As further explained below, this apparatus 100 is capable of rapidly and precisely controlling the temperature of a substrate, including performing thermal etching operations. The apparatus 100 includes a processing chamber 102, a pedestal 104 having a substrate heater 106 and a plurality of substrate supports 108 configured to support a substrate 118, and a gas distribution unit 110.

The processing chamber 102 includes sides walls 112A, a top 112B, and a bottom 112C, that at least partially define the chamber interior 114, which may be considered a plenum volume. It may be desirable in some embodiments to actively control the temperature of the processing chamber walls 112A, top 112B, and bottom 112C in order to prevent unwanted condensation on their surfaces. Some semiconductor processing operations deliver vapors, such as water and/or alcohol vapor, onto the substrate where they adsorb, but they may also undesirably adsorb onto the chamber's interior surfaces. This can lead to unwanted deposition and etching on the chamber interior surfaces which can damage the chamber surfaces and cause particulates to flake off onto the substrate thereby causing substrate defects. In order to reduce and prevent unwanted condensation on the chamber's interior surfaces, the temperature of chamber's walls, top, and bottom may be maintained at a temperature at which condensation of chemistries used in the processing operations does not occur.

This active temperature control of the chamber's surfaces may be achieved by using heaters to heat the chamber walls 112A, the top 112B, and the bottom 112C. As illustrated in FIG. 1, chamber heaters 116A are positioned on and configured to heat the chamber walls 112A, chamber heaters 116B are positioned on and configured to heat the top 112B, and chamber heaters 116C are positioned on and configured to heat the bottom 112C. The chamber heaters 116A-116C may be resistive heaters that are configured to generate heat when an electrical current is flowed through a resistive element. Chamber heaters 116A-116C may also be fluid conduits through which a heat transfer fluid may be flowed, such as a heating fluid which may include heated water. In some instances, the chamber heaters 116A-116C may be a combination of both heating fluid and resistive heaters. The chamber heaters 116A-116C are configured to generate heat in order to cause the interior surfaces of each of the chamber walls 112A, the top 112B, and the bottom 112C to the desired temperature, which may range between about 40° C. and about 150° C., including between about 80° C. and about 130° C., about 90° C. or about 120° C., for instance. It has been discovered that under some conditions, water and alcohol vapors do not condense on surfaces kept at about 90° C. or higher.

The chamber walls 112A, top 112B, and bottom 112C, may also be comprised of various materials that can withstand the chemistries used in the processing techniques. These chamber materials may include, for example, an aluminum, anodized aluminum, aluminum with a polymer, such as a plastic, a metal or metal alloy with a yttria coating, a metal or metal alloy with a zirconia coating, yttria-stabilized zirconia, and a metal or metal alloy with aluminum oxide coating; in some instances the materials of the coatings may be blended or layers of differing material combinations, such as alternating layers of aluminum oxide and yttria, or aluminum oxide and zirconia. These materials are configured to withstand the chemistries used in the processing techniques, such as anhydrous HF, water vapor, methanol, isopropyl alcohol, chlorine, fluorine gases, nitrogen gas, hydrogen gas, helium gas, and mixtures thereof.

The apparatus 100 may also be configured to perform processing operations at or near a vacuum, such as at a pressure of about 0.1 Torr to about 100 Torr, or about 20 Torr to about 200 Torr, or about 0.1 Torr to about 10 Torr. This may include a vacuum pump 184 configured to pump the chamber interior 114 to low pressures, such as a vacuum having a pressure of about 0.1 Torr to about 100 Torr, including about 0.1 Torr to about 10 Torr, and about 20 Torr to about 200 Torr, or about 0.1 Torr to about 10 Torr.

Various features of the pedestal 104 will now be discussed. The pedestal 104 includes a heater 122 (encompassed by the dashed rectangle in FIG. 1) that has a plurality of LEDs 124 that are configured to emit visible light having, e.g., wavelengths of about 400 nm to 800 nm, such as about 450 nm. The heater LEDs emit this visible light onto the backside of the substrate which heats the front side of the substrate. Visible light having wavelengths from about 400 nm to 800 om is able to quickly and efficiently heat silicon substrates from ambient temperature, e.g., about 20° C., to temperatures as high as about 600° C. because silicon absorbs visible light within this range. In contrast, radiant heating, including infrared radiant heating, may ineffectively heat silicon at temperatures up to about 400° C. because silicon tends to be transparent to infrared at temperatures lower than about 400° C. Additionally, radiant heaters that directly heat the topside of a substrate, as in many conventional semiconductor processes, can cause damage or other adverse effects to the topside films. Many “hot plate” heaters that rely on solid-to-solid thermal transference between the substrate and a heating platen, such as a pedestal with a heating coil, have relatively slow to heating and cooling rates. For example, it may take multiple minutes to heat some pedestals to a desired temperature, and from a first to a second higher temperature, as well as to cool the pedestal to a lower temperature. Further, solid-to-solid heating may provide non-uniform heating, which may be caused by substrate warping and inconsistent contact with the heating platen

A heater's plurality of LEDs may be arranged, electrically connected, and electrically controlled in various manners. Each LED may be configured to emit a visible blue light and/or a visible white light. In certain embodiments, white light (produced using a range of wavelengths in the visible portion of the EM spectrum) is used. In some semiconductor processing operations, white light can reduce or prevent unwanted thin film interference. For instance, some substrates have backside films that reflect different light wavelengths in various amounts, thereby creating an uneven and potentially inefficient heating. Using white light can reduce this unwanted reflection variation by averaging out the thin film interference over the broad visible spectrum provided by white light. In some instances, depending on the material on the back face of the substrate, it may be advantageous to use a visible non-white light, such as a blue light having a 450 nm wavelength, for example, in order to provide a single or narrow band of wavelength which may provide more efficient, powerful, and direct heating of some substrates that may absorb the narrow band wavelength better than white light.

Various types of LED may be employed. Examples include a chip on board (COB) LED or a surface mounted diode (SMD) LED. For SMD LEDs, the LED chip may be fused to a printed circuit board (PCB) that may have multiple electrical contacts allowing for the control of each diode on the chip. For example, a single SMD chip may have three diodes (e.g., red, blue, or green) that can be individually controllable to create different colors, for instance. SMD LED chips may range in size, such as 2.8×2.5 mm, 3.0×3.0 mm, 3.5×2.8 mm, 5.0×5.0 mm, and 5.6×3.0 mm. For COB LEDs, each chip can have more than three diodes, such as nine, 12, tens, hundreds or more, printed on the same PCB. COB LED chips typically have one circuit and two contacts regardless of the number of diodes, thereby providing a simple design and efficient single-color application. The ability and performance of LEDs to heat the substrate may be measured by the watts of heat emitted by each LED; these watts of heat may directly contribute to heating the substrate.

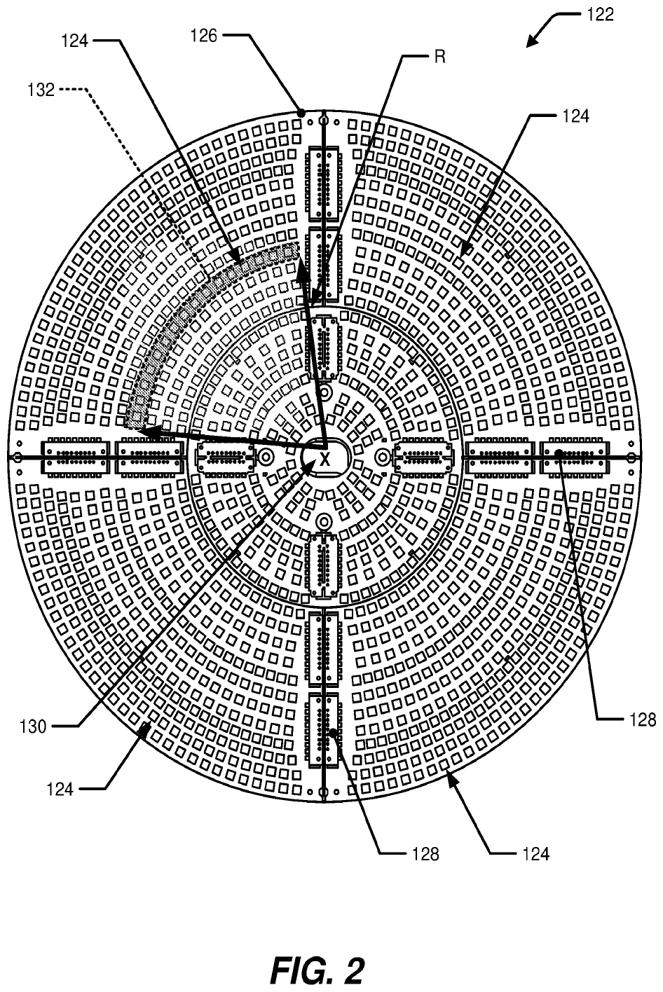

FIG. 2 depicts a top view of a substrate heater with a plurality LEDs. This substrate heater 122 includes a printed circuit board 126 and the plurality of LEDs 124, some of which are labeled. The depicted plurality of LEDs includes approximately 1,300 LEDs. External connections 128 are connected by traces to provide power to the plurality of LEDs 124. As illustrated in FIG. 2, the LEDs may be arranged along numerous arcs that are radially offset from the center 130 of the substrate heater 122 by different radiuses; in each arc, the LEDs may be equally spaced from each other. For example, one arc 132 is surrounded by a partially shaded dotted shape, includes 16 LEDs 124, and is a part of a circle with a radius R that extends around the center 130. The 16 LEDs 124 may be considered equally spaced from each other along this arc 132.

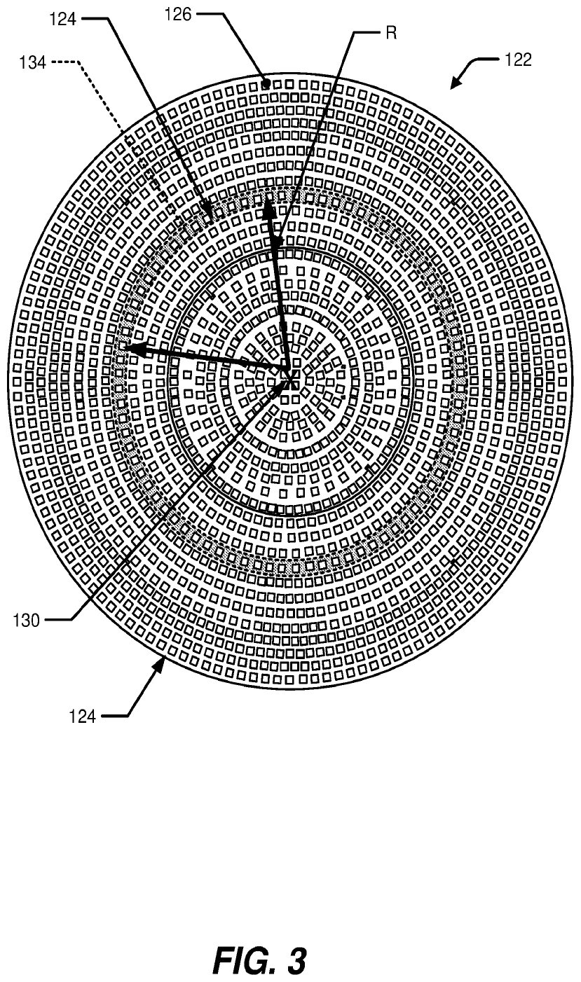

In some embodiments, the LEDs may also be arranged along circles around the center of the substrate heater. In some instances, some LEDs may be arranged along circles while others may be arranged along arcs. FIG. 3 depicts a top view of another example of a substrate heater with a plurality LEDs. The substrate heater 122 of FIG. 3 includes a printed circuit board 126 and the plurality of LEDs 124, some of which are labeled. Here, LEDs 124 are arranged along numerous circles that are radially offset from the center 130 of the substrate heater 122 by different radiuses; in each circle, the LEDs may be equally spaced from each other. For example, one circle 134 is surrounded by a partially shaded ring, includes 78 LEDs 124, and has a radius R that extends around the center 130. The 78 LEDs 124 may be considered equally spaced from each other along this circle 134. The arrangement of the LEDs in FIG. 3 may provide a more uniform light and heat distribution pattern across the entire backside of the substrate compared to the arrangement in FIG. 2 because the regions of the substrate heater 122 in FIG. 2 that contain the external connections may provide unheated cold spots on the substrate, especially because the substrate and heater remain stationary with respect to each other during processing; the substrate and the substrate heater do not rotate.

In some embodiments, the plurality of LEDs may include at least about 1,000 LEDs, including about 1,200, 1,500, 2,000, 3,000, 4,000, 5,000, or more than 6,000, for instance. Each LED may, in some instances, be configured to uses about 4 watts or less at 100% power, including about 3 watts at 100% power and about 1 watt at 100% power. These LEDs may be arranged and electrically connected into individually controllable zones to enable temperature adjustment and fine tuning across the substrate. In some instances, the LEDs may be grouped into at least 20, for instance, independently controllable zones, including at least about 25, 50, 75, 80, 85 90, 95, or 100 zones, for instance. These zones may allow for temperature adjustments in the radial and azimuthal (i.e., angular) directions. These zones can be arranged in a defined pattern, such as a rectangular grid, a hexagonal grid, or other suitable pattern for generating a temperature profile as desired. The zones may also have varying shapes, such as square, trapezoidal, rectangular, triangular, obround, elliptical, circular, annular (e.g., a ring), partially annular (e.g., an annular sector), an arc, a segment, and a sector that may be centered on the center of the heater and have a radius less than or equal to the overall radius of the substrate heater's PCB. For example, in FIG. 2 the LEDs have 88 zones that are organized into at least 20, such as 20 or 21, concentric rings. These zones are able to adjust the temperature at numerous locations across the substrate in order to create a more even temperature distribution as well as desired temperature profiles, such as higher temperatures around the edge of the substrate than in the center of the substrate. The independent control of these zones may also include the ability to control the power output of each zone. For example, each zone may have at least 15, 20, or 25 adjustable power outputs. In some instances, each zone may have one LED thereby enabling each LED to be individually controlled and adjusted which can lead to a more uniform heating profile on the substrate. Accordingly, in some embodiments, each LED of the plurality of LEDs in the substrate heater may be individually controllable.

In certain embodiments, the substrate heater 122 is configured to heat the substrate to multiple temperatures and maintain each such temperature for various durations. The substrate heater may be configured to heat the substrate to between about 50° C. and 600° C., including to any temperature or range between these temperatures. Additionally, in some embodiments, the substrate heater 122 is configured to heat the substrate to any temperature within these ranges in less than about 60 seconds, less than about 45 seconds, less than about 30 seconds, or less than about 15 seconds, for instance. In certain embodiments, the substrate heater 122 is configured to heat a substrate at one or more heating rates, such as between at least about 0.1° C./second and at least about 20° C./second, for example.

The substrate heater may increase the temperature of the substrate by causing the LEDs to emit the visible light at one or more power levels, including at least about 80%, at least about 90%, at least about 95%, or at least about 100% power. In some embodiments, the substrate heater is configured to emit light between about 10 W and 4000 W, including at least about 10 W, at least about 30 W, at least about 0.3 kilowatt (kW), at least about 0.5 kW, at least about 2 kW, at least about 3 kW, or at least about 4 kw. The apparatus is configured to supply between about 0.1 kw and 9 kW of power to the pedestal; the power supply is connected to the substrate heater through the pedestal but is not depicted in the Figures. During temperature ramps, the substrate heater may operate at the high powers, and may operate at the lower power levels (e.g., including between about 5 W and about 0.5 kW) to maintain the temperature of a heated substrate.

The pedestal may include reflective material on its internal surfaces that, during operation, reflects and directs the light emitted by the LEDs onto the backside of the substrate supported by the pedestal. In some such embodiments, the substrate heater may include such reflective material positioned on a top surface 140, as shown in FIG. 1, of the PCB 126 on which the plurality of LEDs 124 is positioned. The reflective material may be comprised of aluminum, such as polished aluminum, stainless steel, aluminum alloys, nickel alloys, and other protective layers which can prevent oxidation of the metal and/or enhance the reflectivity at specific wavelengths, such as reaching greater than 99% reflectivity for specific wavelengths, and other durable reflective coatings. Additionally, or alternatively, the pedestal 104 may have a bowl 146 in which the substrate heater 122 is at least partially positioned. The bowl 146 may have exposed internal surfaces 148 of the pedestal sidewalls 149 upon which the reflective material may be positioned. This reflective material increases the heating efficiency of the substrate heater and reduces the unwanted heating of the PCB 126 and pedestal 104 by advantageously directing light back onto the substrate that would have otherwise been absorbed by the PCB 126 and the pedestal 104.

In some embodiments, the substrate heater may also include a pedestal cooler that is thermally connected to the LEDs such that heat generated by the plurality of LEDs can be transferred from the LEDs to the pedestal cooler. This thermal connection allows heat to be conducted from the plurality of LEDs to the pedestal cooler along one or more heat flow pathways between these components. In some instances, the pedestal cooler is in direct contact with one or more elements of the substrate heater, while in other instances other conductive elements, such as thermally conductive plates (e.g., that comprise a metal) are interposed between the substrate heater and the pedestal cooler. Referring back to FIG. 1, the substrate heater includes a pedestal cooler 136 in direct contact with the bottom of the PCB 126. Heat is configured to flow from the LEDs to the PCB 126, and to the pedestal cooler 136. The pedestal cooler 136 also includes a plurality of fluid conduits 138 through which a heat transfer fluid, such as water, is configured to flow in order to receive the heat and thus cool the LEDs in the substrate heater 122. The fluid conduits 138 may be connected to a reservoir and pump, not pictured, located outside the chamber. In some instances, the pedestal cooler may be configured to flow water that is cooled, such as between about 5° C. and 20° C.

As provided herein, it may be advantageous to actively heat the exterior surfaces of the processing chamber 102. In some instances, it may similarly be advantageous to heat the exterior surfaces of the pedestal 104 to prevent unwanted condensation and deposition on its external surfaces. As illustrated in FIG. 1, the pedestal 104 may further include a pedestal heater 144 inside of the pedestal 104 that is configured to heat the exterior surfaces of the pedestal 104, including its sides 142A and bottom 142B. The pedestal heater 144 may include one or more heating elements, such as one or more resistive heating elements and fluid conduits in which a heating fluid is configured to flow. In some instances, the pedestal cooler and the pedestal heater may both have fluid conduits that are fluidically connected to each other such that the same heat transfer fluid may flow in both the pedestal cooler and the pedestal heater. In these embodiments, the fluid may be heated to between 50° C. and 130° C. including about 90° C. and 120° C.

The pedestal may also include a window to protect the substrate heater, including the plurality of LEDs, from damage caused by exposure to the processing chemistries and pressures used during processing operations. As illustrated in FIG. 1, the window 150 may be positioned above the substrate heater 122 and may be sealed to the sidewall 149 of the pedestal 104 in order to create a plenum volume within the pedestal that is fluidically isolated from the chamber interior. This plenum volume may also be considered the inside of the bowl 146. The window may be comprised of one or more materials that are optically transparent to the visible light emitted by LEDs, including light having wavelengths in the range of 400 nm to 800 nm. In some embodiments, this material may be or comprise quartz, sapphire, quartz with a sapphire coating, quartz with a coating which is IR reflective and visible transmissive, calcium fluoride (CaF), spinel, and/or AlON. The window may also not have any holes or openings within it. In some embodiments, the heater may have a thickness of about 15 to 30 mm, including about 20 mm and about 25 mm.

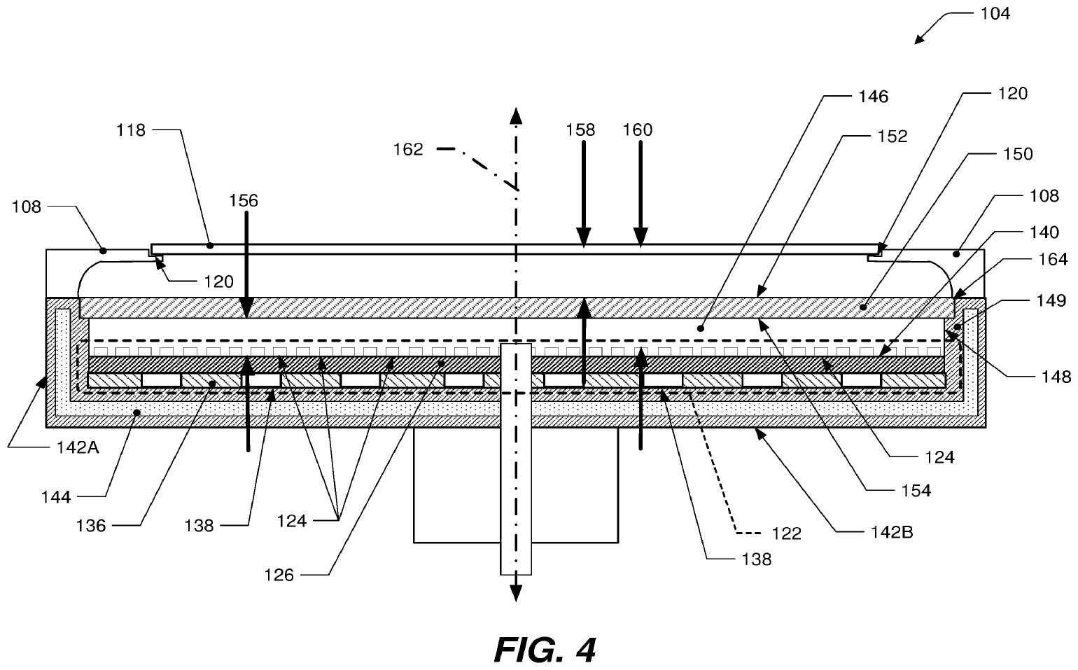

FIG. 4 depicts the pedestal of FIG. 1 with additional features in accordance with various embodiments. As identified in FIG. 4, the window 150 includes a top surface 152 that faces the substrate 118 supported by the pedestal 104, and a bottom surface 154 that faces the substrate heater 122. In some embodiments, the top and the bottom surfaces 152 and 154 may be flat, planar surfaces (or substantially flat, e.g., within ±10% or 5% of flat). In some other instances, the top 152, bottom 154, or both top 152 and bottom 154 may be nonplanar surfaces. The nonplanarity of these surfaces may be configured to refract and/or direct the light emitted by the substrate heater's 122 LEDs 124 to more efficiently and/or effectively heat the substrate. The nonplanarity may also be along some or all of the surface. For example, the entire bottom surface may have a convex or concave curvature, while in another example an outer annular region of the bottom surface may have a convex or concave curvature while the remaining portion of the surface is planar. In further examples, these surfaces may have multiple, but different, nonplanar sections, such as having a conical section in the center of the surface that is adjacent to a planar annular section, that is adjacent to a conical frustum surface at the same or different angle as the conical section. In some embodiments, the window 150 may have features that act as an array of lenses which are oriented to focus the light emitted by one or more LEDs, such as each LED.

With the window 150 positioned above the substrate heater 122, the window 150 gets heated by the substrate heater 122 which can affect the thermal environment around the substrate. Depending on the material or materials used for the window 150, such as quartz, the window may retain heat and progressively retain more heat over the course of processing one or more substrates. This heat can get radiatively transferred to the substrate and therefore directly heat the substrate. In some instances, that the window can cause a temperature increase of between 50° C. and 80° C. above the heater temperature. This heat may also create a temperature gradient through the thickness, or in the vertical direction, of the window. In some instances, the top surface 152 is 30° C. hotter than the bottom surface 154. It may therefore be advantageous to adjust and configure the chamber to account for and reduce the thermal effects of the window. This may include detecting the substrate's temperature and adjusting the substrate heater to account for the heat retained by the window.

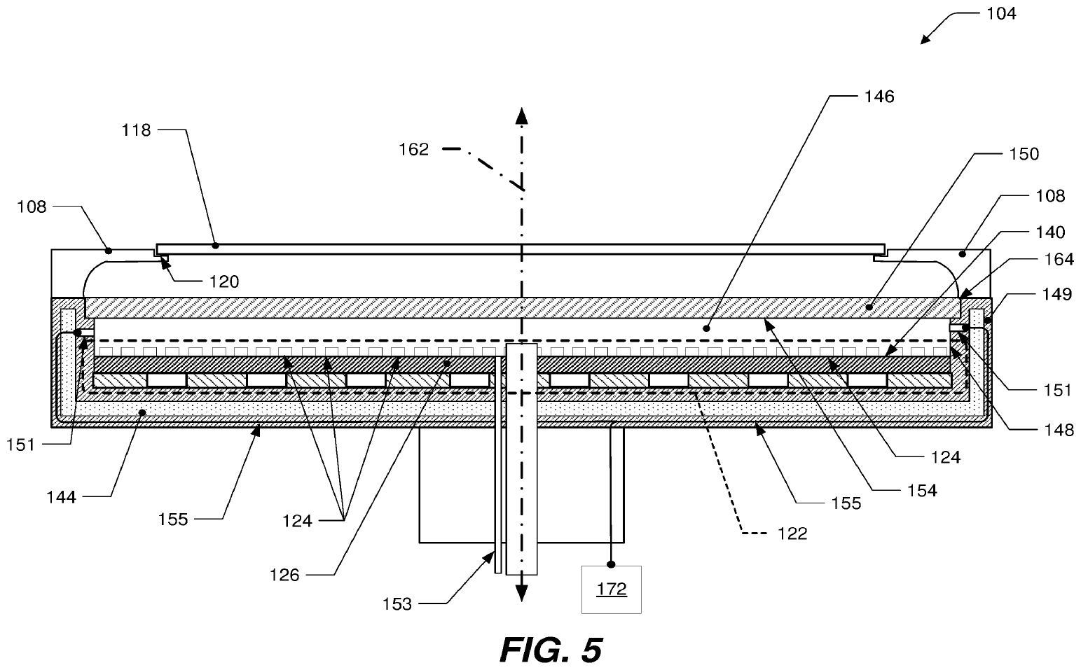

This may also include various configurations of the pedestal, such as actively cooling the window. In some embodiments, like that shown in FIGS. 1 and 4, the window 150 may be offset from the substrate heater 122 by a first distance 156. In some embodiments, this first distance may be about 2 mm to 50 mm, including about 5 mm to 40 mm. A cooling fluid, such as an inert gas, may be flowed between the window 150 and the substrate heater 122 in order to cool both the window 150 and the substrate heater 122. The pedestal may have one or more inlets and one or more outlets for flowing this gas within the plenum volume, or bowl 146, of the pedestal 104. The one or more inlets are fluidically connected to the inert gas source outside the processing chamber 102, which may include through fluid conduits that may be at least partially routed inside the pedestal 104. The one or more outlets are fluidically connected to an exhaust or other environment outside the processing chamber 102, which may also be through fluid conduits running within the pedestal. In FIG. 5, which depicts the pedestal of FIG. 4 with additional features in accordance with various embodiments, one or more inlets 151 are positioned in the sidewalls 149 and extend through the internal surface 148; the one or more inlets are also fluidically connected to a gas source 172 (e.g., an inert gas source) through, in part, fluid conduits 155 that are routed through the pedestal 104. A single outlet 153 is positioned in a center region, i.e., not in the exact center but in close proximity, of the substrate heater 122. In some embodiments, the one or more gas inlets and one or more outlets may be switched, such that the one or more outlets extend through the sidewalls 149 (i.e., they are items 151 in FIG. 5), and the one or more inlets may be the center region of the substrate heater 122 (i.e., they are item 153 in FIG. 5). In some embodiments, there may be more than one outlet; in some embodiments, there may only be a single gas inlet. In some embodiments, one or more gas inlets extend through the internal surface 148 of the pedestal sidewall 149 underneath the LED heater 122 and one or more gas outlets extend through another part of the pedestal sidewall 149, such as a mounting bracket between the LED heater 122 and the pedestal sidewall 149.

In some embodiments, the window may be placed in direct, thermal contact with the substrate heater and the pedestal cooler may be configured to cool both the PCB and the window. In some embodiments, as also shown in FIGS. 1 and 4, the window 150 may be thermally connected to the sidewalls 149 of the pedestal 104 in order to transfer some of the retained heat in the window 150 to the pedestal 104. This transferred heat may be further transferred out of the pedestal using, for instance, the pedestal heater 144 which may flow fluid through the pedestal 104 that is heated to between about 20° C. and 100° C., for instance. This heated fluid may be cooler than the temperature of the pedestal 104 at the thermal connection with the window 150. In some embodiments, the window 150 may have one or more fluid conduits within the window 150 through which transparent cooling fluid may be configured to flow. The fluid may be routed to the window through the pedestal from a fluid source or reservoir outside the chamber.

Further discussion of certain embodiments, including materials of fabrication appears below. Judicious choice of the window material and/or the contact pad construction can mitigate some of the issues discussed above.

As shown in FIGS. 1 and 4, the pedestal's 104 substrate supports 108 (sometimes referred to herein as support pads) are configured to support the substrate 118 above and offset from the window 150 and the substrate heater 122. In certain embodiments, the temperature of the substrate can be rapidly and precisely controlled by thermally floating, or thermally isolating, the substrate within the chamber. It is desirable to position the substrate so that the smallest thermal mass is heated and cooled. This thermal floating is configured to position the substrate so that it has minimal thermal contact (which includes direct and radiation) with other solid bodies in the chamber.

The pedestal 104 is therefore configured, in some embodiments, to support the substrate 118 by thermally floating, or thermally isolating, the substrate within the chamber interior 114. The pedestal's 104 plurality of substrate supports 108 are configured to support the substrate 118 such that the thermal mass of the substrate 118 is reduced as much as possible to the thermal mass of just the substrate 118. Each substrate support 108 may have a substrate support surface 120 that provides minimal contact with the substrate 118. The number of substrate supports 108 may be at least 3, at least 6 or more. The surface area of the support surfaces 120 may also be the minimum area required to adequately support the substrate during processing operations (e.g., to support the weight of the substrate and prevent inelastic deformation of the substrate). Further embodiments relating to substrate supports (also referred to as pad supports are described below).

The substrate supports are also configured to prevent the substrate from being in contact with other elements of the pedestal, including the pedestal's surfaces and features underneath the substrate. As seen in FIGS. 1 and 4, the substrate supports 108 hold the substrate 118 above and offset from the next adjacent surface of the pedestal 104 below the substrate 118, which is the top surface 152 (identified in FIG. 4) of the window 150. As can be seen in these Figures, a volume or gap exists underneath the substrate, except for the contact with the substrate supports. As illustrated in FIG. 4, the substrate 118 is offset from the top surface 152 of the window 150 by a distance 158. This distance 158 may affect the thermal effects caused by the window 150 to the substrate 118. The larger the distance 158, the less the effects. It was found that a distance 158 of about 2 mm or less resulted in a significant thermal coupling between the window and the substrate; it is therefore desirable to have a larger distance 158 than 2 mm, such as at least about 5 mm, about 10 mm, about 15 mm, about 20 mm, about 30 mm, about 50 mm, or about 100 mm, for example.

The substrate 118 is also offset from the substrate heater 122 (as measured in some instances from a top surface of the substrate heater 122 which may be the top surface of the LEDs 124) by a distance 160. This distance 160 affects numerous aspects of heating the substrate 118. In some embodiments, a distance 160 of about 10 mm to 90 mm, or about 5 mm to 100 mm, including about 10 mm to 30 mm. The offset may be chosen to provide a substantially uniform heating pattern and acceptable heating efficiency.

As stated, the substrate supports 108 are configured to support the substrate 118 above the window. In some embodiments, these substrate supports are stationary and fixed in position; they are not lift pins or a support ring. In some embodiments, at least a part of each substrate support 108 that includes the support surface 120 may be comprised of a material that is transparent at least to light emitted by LEDS 124. This material may be, in some instances, quartz or sapphire. The transparency of these substrate supports 108 may enable the visible light emitted by the substrate heater's 122 LEDs to pass through the substrate support 108 and to the substrate 118 so that the substrate support 108 does not block this light and the substrate 118 can be heated in the areas where it is supported. This may provide a more uniform heating of the substrate 118 than with a substrate support comprising a material opaque to visible light.

In some embodiments, such as those shown in FIG. 4, the substrate supports 108 may be positioned closer to a center axis 162 of the window than the outer diameter 164 of the window 150. In some instances, portions of these substrate supports may extend over and above the window 150.

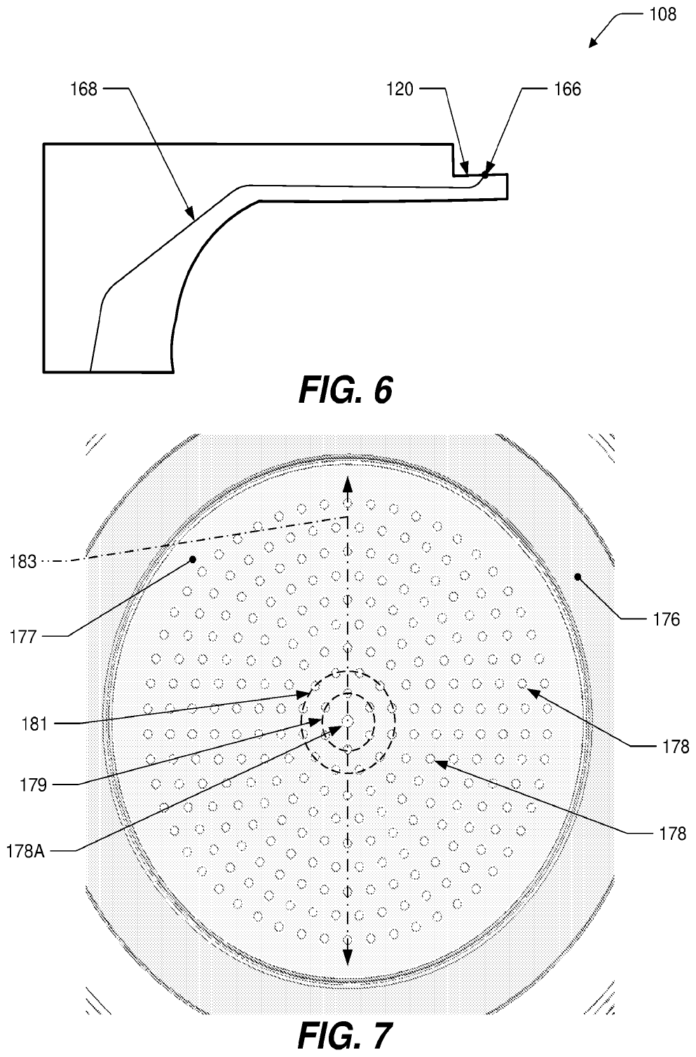

In some embodiments, the substrate supports may each contain a temperature sensor that is configured to detect the temperature of the substrate positioned on the support surface of the substrate supports. FIG. 6 depicts a substrate support of FIGS. 1 and 4 in accordance with disclosed embodiments. Here, the support surface 120 of the substrate support 108 is identified, along with a temperature sensor 166. In some embodiments, this temperature sensor 166 extends through the support surface 120 such that the temperature sensor 166 is in direct contact with a substrate held by the support surface 120. In some other embodiments, the temperature sensor 166 is positioned within the substrate support 108 and below the support surface 120. In some embodiments, this temperature sensor 166 is a thermocouple. In some other embodiments, the temperature sensor 166 may be a thermistor, a resistance temperature detector (RTD), and semiconductor sensor. The electrical wiring 168 for the temperature sensor 166 may be routed through the substrate support 108 and may also be routed through the pedestal 104.

Referring back to FIG. 1, in some embodiments, the pedestal is also configured to move vertically. This may include moving the pedestal such that a gap 186 between a faceplate 176 of the gas distribution unit 110 and the substrate 118 is capable of being in a range between about 2 mm and 70 mm. Moving the pedestal vertically may enable active cooling of the substrate as well as rapid cycling time of processing operations, including flowing gas and purging, due to a low volume created between the gas distribution unit 110 and the substrate 118. This movement may also enable the creation of a small process volume between the substrate and the gas distribution unit which can result in a smaller purge and process volumes and thus reduce purge and gas movement times and increase throughput.

The gas distribution unit 110 is configured to flow process gases, which may include liquids and/or gases, such as a reactant, modifying molecules, converting molecules, or removal molecules, onto the substrate 118 in the chamber interior 114. As seen in FIG. 1, the gas distribution unit 110 includes one or more fluid inlets 170 that are fluidically connected to one or more gas sources 172 and/or one or more vapor sources 174. In some embodiments, the gas lines and mixing chamber may be heated to prevent unwanted condensation of the vapors and gases flowing within. These lines may be heated to at least about 40° C., at least about 80° C., at least about 90° C., at least about 120° C., at least about 130° C., or at least about 150° C. The one or more vapor sources may include one or more sources of gas and/or liquid which is vaporized. The vaporizing may be a direct inject vaporizer, a flow over vaporizer, or both. The gas distribution unit 110 also includes the faceplate 176 that includes a plurality of through-holes 178 that fluidically connect the gas distribution unit 110 with the chamber interior 114. These through-holes 178 are fluidically connected to the one or more fluid inlets 170 and also extend through a front surface 177 of the faceplate 176, with the front surface 177 configured to face the substrate 118. In some embodiments, the gas distribution unit 110 may be considered a top plate and in some other embodiments, it may be considered a showerhead.

The through-holes 178 may be configured in various ways to deliver uniform gas flow onto the substrate. In some embodiments, these through-holes may all have the same outer diameter, such as between about 0.03 inches and 0.05 inches, including about 0.04 inches (1.016 mm). These faceplate through-holes may also be arranged throughout the faceplate in order to create uniform flow out of the faceplate.

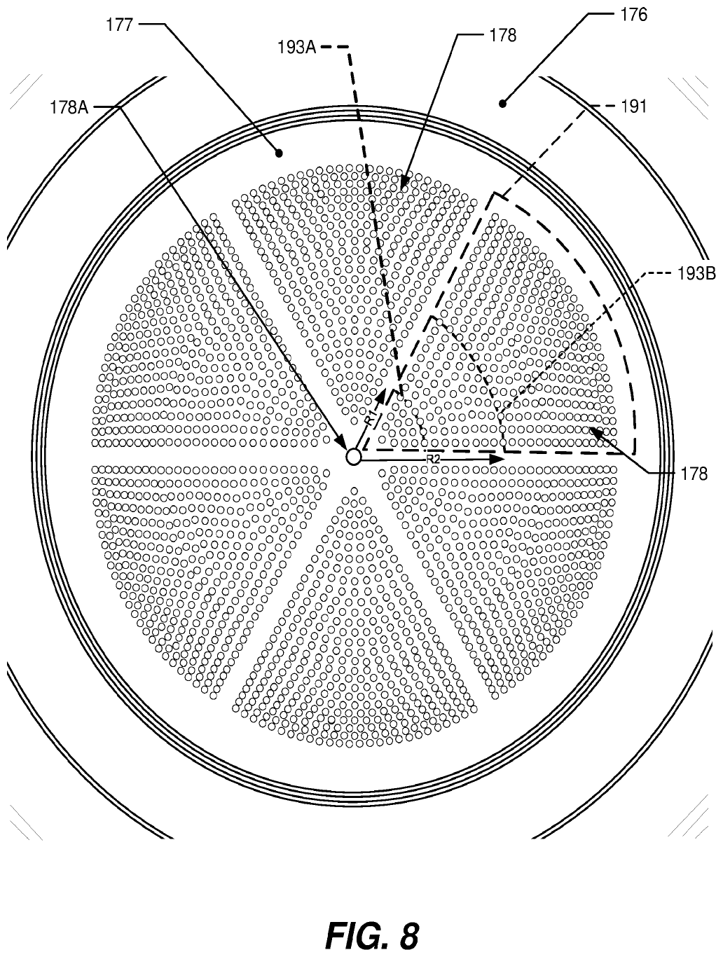

FIG. 7 depicts a plan view of first example faceplate 176 with the front surface 177 (the surface configured to face a substrate) and the through-holes 178 visible. As can be seen, the faceplate 176 through-holes 178 extend through the faceplate 176 and the front surface 177. These through-holes are also arranged along multiple circles that are centered around the center axis of the faceplate, thereby offsetting the holes from each other. As illustrated, some circles of through-holes 178 may be centered on a referential datum 183, while other circles of the through-holes are offset from the referential datum 183 by an angle, such as about 15°, 7.5°, etc. Here, the through-holes along the first circle 179 include two through-holes centered on the referential datum 183, while the through-holes along the second circle 181 are not centered on the referential datum 183 and are offset from the datum 183 by about 15°. The concentric circles of through-holes may alternate between holes centered on the datum 183 and offset from the datum 183.

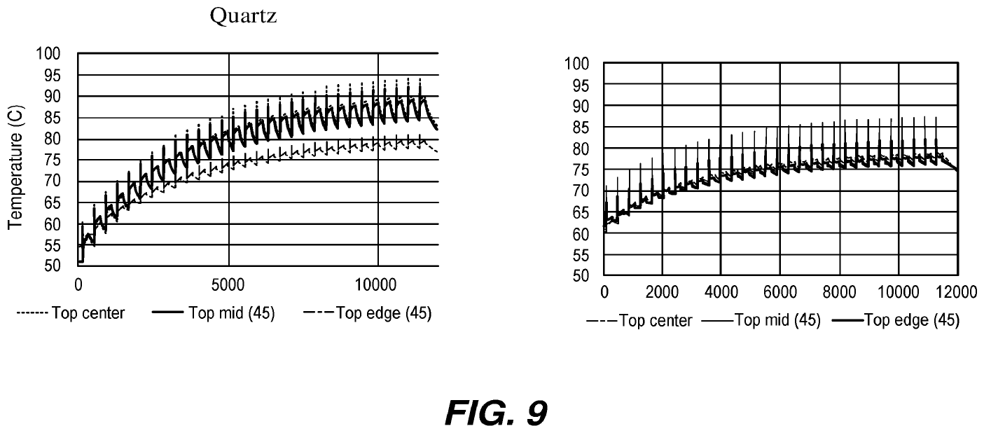

FIG. 8 depicts a plan view of second example faceplate 176 with the front surface 177 (the surface configured to face a substrate) and the through-holes 178 visible. As can be seen, the faceplate 176 through-holes 178 extend through the faceplate 176 and the front surface 177. These through-holes are arranged different than in FIG. 7, with one through-hole 178 centered on the center axis of the faceplate 176, and the remaining through-holes 178 arranged in 6 sectors, such that in each sector, the through-holes are equally spaced along arcs in the sector. For instance, one sector 191 is illustrated within a dashed line, and the holes are arranged along a plurality of arcs within the sector that increase as their radial distance from the center of the faceplate 176 increases. A first example arc 193A is identified along which 6 through-holes 178 are equally spaced, and a second example arc 193B is identified along which 12 through-holes are equally spaced. The second example arc 193B is larger than the first example arc 193A and has a greater radial distance R2 than the first arc's 193A radial distance R1.

Referring back to FIG. 1, the gas distribution unit 110 may also include a unit heater 180 that is thermally connected to the faceplate 176 such that heat can be transferred between the faceplate 176 and the unit heater 180. The unit heater 180 may include fluid conduits in which a heat transfer fluid may be flowed. The heat transfer fluid may be heated to a temperature range of about 20° C. and 120° C., for example. In some instances, the unit heater 180 may be used to heat the gas distribution unit 110 to prevent unwanted condensation of vapors and gases; in some such instances, this temperature may be at least about 90° C. or 120° C.

In some embodiments, the gas distribution unit 110 may include a second unit heater 182 that is configured to heat the faceplate 176. This second unit heater 182 may include one or more resistive heating elements, fluid conduits for flowing a heating fluid, or both. Using two unit heaters 180 and 182 in the gas distribution unit 110 may enable various heat transfers within the gas distribution unit 110. This may include using the first and/or second unit heaters 180 and 182 to heat the faceplate 176 in order to provide a temperature-controlled chamber, as described above, in order to reduce or prevent unwanted condensation on elements of the gas distribution unit 110.

The apparatus 100 may also be configured to cool the substrate. This cooling may include flowing a cooling gas onto the substrate, moving the substrate close to the faceplate to allow heat transfer between the substrate and the faceplate, or both. Actively cooling the substrate enables more precise temperature control and faster transitions between temperatures which reduces processing time and improves throughput. In some embodiments, the first unit heater 180 that flows the heat transfer fluid through fluid conduits may be used to cool the substrate 118 by transferring heat away from the faceplate 176 that is transferred from the substrate 118. A substrate 118 may therefore be cooled by positioning it in close proximity to the faceplate 176, such as by a gap 186 of less than or equal to 5 mm or 2 mm, such that the heat in the substrate 118 is radiatively transferred to the faceplate 176 and transferred away from the faceplate 176 by the heat transfer fluid in the first unit heater 180. The faceplate 176 may therefore be considered a heat sink for the substrate 118 in order to cool the substrate 118.

In some embodiments, the apparatus 100 may further include a cooling fluid source 173, which may contain a cooling fluid (a gas or a liquid), and a cooler (not pictured) configured to cool the cooling fluid to a desired temperature, such as less than or equal to about 90° C., less than or equal to about 70° C., less than or equal to about 50° C., less than or equal to about 20° C., less than or equal to about 10° C., less than or equal to about 0° C. less than or equal to about −50° C., less than or equal to about −100° C., less than or equal to about −150° C., less than or equal to about −190° C., about −200° C., or less than or equal to about −250° C., for instance. The apparatus 100 includes piping to deliver the cooling fluid to the one or more fluid inlets 170, and the gas distribution unit 110 which is configured to flow the cooling fluid onto the substrate. In some embodiments, the fluid may be in liquid state when it is flowed to the processing chamber 102 and may turn to a vapor state when it reaches the chamber interior 114, for example if the chamber interior 114 is at a low pressure state, such as described above, e.g., between about 0.1 Torr and 10 Torr, or between about 0.1 Torr and 100 Torr, or between about 20 Torr and 200 Torr, for instance. The cooling fluid may be an inert element, such as nitrogen, argon, or helium. In some instances, the cooling fluid may include, or may only have, a non-inert element or mixture, such as hydrogen gas. In certain embodiments, the apparatus may be configured to cool a substrate at one or more cooling rates, such as at least about 5° C./second, at least about 10° C./second, at least about 15° C./second, at least about 20° C./second, at least about 30° C./second, or at least about 40° C./second.

In some embodiments, the apparatus 100 may actively cool the substrate by both moving the substrate close to the faceplate and flowing cooling gas onto the substrate. In some instances, the active cooling may be more effective by flowing the cooling gas while the substrate is in close proximity to the faceplate. The effectiveness of the cooling gas may also be dependent on the type of gas used.

In some embodiments, the apparatus 100 may include a mixing plenum for blending and/or conditioning process gases for delivery before reaching the fluid inlets 170. One or more mixing plenum inlet valves may control introduction of process gases to the mixing plenum. In some other embodiments, the gas distribution unit 110 may include one or more mixing plenums within the gas distribution unit 110. The gas distribution unit 110 may also include one or more annular flow paths fluidically connected to the through-holes 178 which may equally distribute the received fluid to the through-holes 178 in order to provide uniform flow onto the substrate.

The apparatus 100 may include one or more optical sensors 198 to detect one or more features of the visible light emitted by the LEDs. In some embodiments, these optical sensors may be one or more photodetectors configured to detect the light and/or light intensity of the light emitted by the LEDs of the substrate heater. In FIG. 1, a single optical sensor 198 is shown as connected to the chamber interior 114 via fiberoptic connection such that the optical sensor 198 is able to detect light emitted by the substrate heater 122. The optical sensor 198, and additional optical sensors, can be positioned in various locations in the top and sides, for instance, of the processing chamber 102 to detect the emitted light at various locations within the processing chamber 102. As discussed below, this may enable the measurement and adjustment of the substrate heater, such as the adjustment of one or more independently controllable zones of the LEDs. In some embodiments, there may be a plurality of optical sensors 198 arranged along a circle or multiple concentric circles to measure various regions of the LEDs throughout the processing chamber 102. In some embodiments, the optical sensors may be positioned inside the chamber interior 114.

The apparatus 100 may also include one or more additional non-contact sensors for detecting the temperature of the substrate. Such sensors may include pyrometers, for instance. Although conventional pyrometers are not able to detect certain substrates within particular temperature ranges, the pyrometer described here overcomes these problems. For instance, the pyrometer is configured to detect multiple emission ranges to detect multiple types of substrates, e.g., doped, low doped, or not doped, at various temperature ranges. This includes a configuration to detect emission ranges of about 0.95 microns to about 1.1 microns, about 1 micron, about 1 to about 4 microns, and/or about 8 to 15 microns. The pyrometer is also configured to detect the temperature of a substrate at a shorter wavelength to differentiate the signal from the thermal noise of the chamber.

The pyrometer may include an emitter configured to emit infrared signals and a detector configured to receive emissions. Referring to FIG. 1, the apparatus includes the pyrometer 188 having an emitter within the pyrometer 188 and a detector 190. The pyrometer may be configured to emit signals on one side of the substrate, either the top or the bottom, and configured to receive signals on the other side of the substrate. For instance, the emitter may emit signals on the top of the substrate and the detector is under the substrate and receives signals emitted through and under the substrate. The apparatus may therefore have at least a first port 192A on the top of the processing chamber 102, such as the port 192A through the center of the gas distribution unit 110, and a second port 192B through the pedestal 104 and substrate heater 122. The emitter in the pyrometer 188 may be connected to one of the ports 192A or 192B via a fiberoptic connection, such as the first port 192A as shown in FIG. 1, and the detector is optically connected to the other port, such as the second port 192B in FIG. 1. The first port 192A may include a port window 194 to seal the first port 192A from the chemistries within the chamber interior 114. The second port 192B is seen in FIG. 1 extending through the pedestal 104 and the substrate heater such that the emitter's emissions can pass through the substrate, through the window 150, into the second port 192B and to the detector 190 that may be positioned in the second port or optically connected to the second port through another fiberoptic connection (not shown). In some other embodiments, the emitter and the detector are flipped, such that the emitter emits through the second port 192B and the detector detects through the first port 192A.

As explained, the window material can have a significant impact on process reliability as well as the window's durability. For example, if a window becomes less transparent—such as by formation of a haze—it reduces the amount of power transferred from radiative heat elements to the substrate surface. As a consequence, the substrate temperature decreases, which may cause the process to shift. For example, the lower temperatures may cause a higher thermal etch rate. Additionally, the window may need to be replaced frequently.

The following includes some comparative information about quartz and sapphire as window materials. In aggressive etch vapor environments, it has been observed that the mass change of quartz is more than 10000 times that of sapphire. It has been observed that AlON and spinel (MgAl₂O₄) are also more resistant than quartz to such environments. Additionally, sapphire has over 28 times higher thermal conductivity than quartz. And sapphire has greater than 11 times the mechanical strength of quartz. Further, sapphire absorbs less thermal IR than quartz.

The table below provides a comparison of physical properties of quartz and certain other window materials.

| Material | Quartz | ALON | Spinel | Sapphire |
|---|---|---|---|---|
| Young's Modulus (GPa) | 70 | 320 | 276 | 400 |
| Flexure Strength (MPa) | 80 | 300-700 | 170 | 900 |
| Specific Heat (J/kg-K) | 670 | 921 | 819 | 750 |
| Thermal Conductivity (W/m-K) | 1.4 | 12.6 | 25 | 40 |
| Thermal Expansion Coeff. | 5.00E−07 | 6.00E−06 | 7.00E−06 | 4.50E−06 |

Other materials that may be used in a window include IR Grade fused silica, magnesium fluoride (MgF₂), calcium fluoride (CaF₂), barium fluoride (BaF₂).

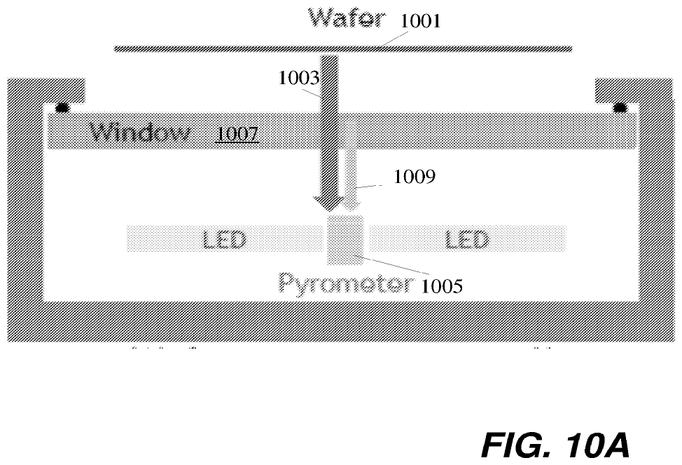

FIG. 9 shows the differences in the abilities of quartz and sapphire windows to reach steady temperature and follow temperature changes when exposed to thermal cycling. The top center refers to a position near the middle of a disk-shaped window. The top edge refers to a radial position at the edge or perimeter of the window. The mid center refers to a radial position near the midway way point between the center and edge of the window. From this data, it can be seen that, in comparison to the quartz window, the sapphire window (a) reaches a steady-state temperature faster, (b) has a more uniform center-edge temperature profile, and (c) operates at cooler temperature.

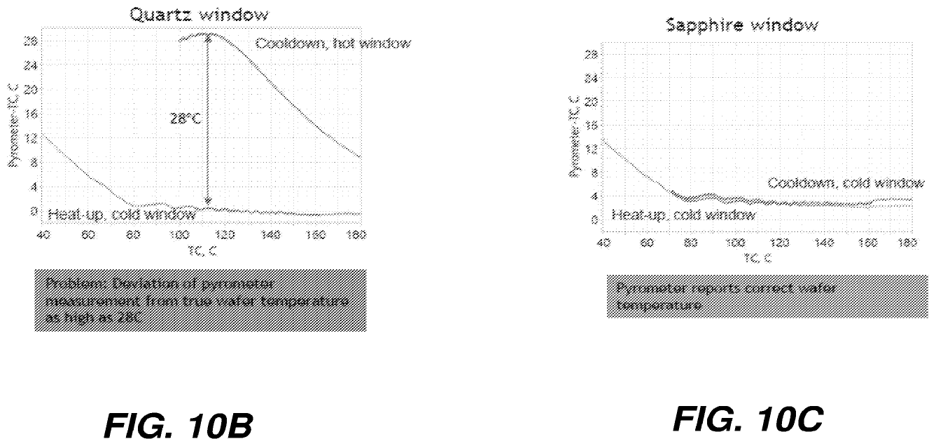

A sapphire window can also improve the accuracy of wafer thermometry. FIG. 10A illustrates a mechanism of pyrometry and how a window can interfere with that mechanism. In the depicted embodiment, a wafer 1001 being measured emits radiation 1003 over a range of wavelengths. The spectral distribution and the intensity of the emitted radiation is a function of the wafer's temperature. Pyrometry relies on this property and measures emitted radiation intensity at a particular wavelength. If the pyrometer (e.g., pyrometer 1005) only detects radiation emitted by wafer, it can reliably measure the wafer's temperature. But when a window (e.g., window 1007) also emits thermal radiation 1009, the pyrometer detects radiation contributed by both wafer 1001 and window 1007. Because the thermometry system typically cannot determine the relative contributions of the wafer and the window to the detected radiation, it cannot reliably measure a wafer's temperature.

By contrast, a sapphire window does not significantly interfere with pyrometer readings. This is partly because a sapphire window runs cooler than a quartz window. It can have a smaller size, higher specific heat, and consequently hold less heat at a given temperature. Additionally, sapphire has a lower emissivity at a typical pyrometer wavelength (e.g., 2.3 um) than quartz.

The thermal properties of quartz coupled with the need to make quartz windows relatively large (due to quartz's mechanical properties) cause quartz windows to emit more radiation during cooling than during heating. This difference further complicates interpretation of pyrometer readings. FIG. 10B illustrates the disparate effect of heating and cooling on a quartz window's emissions and pyrometry readings. FIG. 10C illustrates that a sapphire window's emissions do not similarly complicate pyrometry readings.

In certain embodiments, a sapphire, AlON, or spinel window has thickness of about 5 to 40 mm or about 7 to 15 mm for, e.g., a 300 mm diameter window. The thickness may scale the window diameter. In certain embodiments, a sapphire, AlON, or spinel window has diameter of about 250 to 500 mm or about 300 to 400 mm.

As indicated, a substrate undergoing processing is supported by support pads, of which pads 108 provide one example. In some embodiments, the support pads should introduce little or no perturbation of substrate temperature. Such perturbation can be caused by heat conduction and/or blockage of LED light by the support pads. Additionally, in some embodiments, support pads comprise a material that exhibits chemical resistance to the chamber environment such as an aggressive etchant gas.

The inventors have observed that some the perimeter region of a wafer substrate may exhibit cold spots where support pads are located. In some cases, the cold spot may be about 5° C. or greater, and sometimes 20° C. or greater. These cold spots may be distributed azimuthally around the perimeter of the substrate, corresponding to the locations of the support pads. Such substrate temperature non-uniformity directly translates into high process rate non-uniformity (e.g., high etch rate non-uniformity), which is not acceptable for many applications.

Such non-uniformity has been found to occur with aluminum or anodized aluminum support pads. These support pads may have a generally triangular shape on or proximate to a contact point with the substrate.

The source of the cold spots may be heat conduction away from (or to) the substrate via the support pads. Considering the relevant heat transfer physics, one may consider the heat conduction equation:

$$\frac{Q}{Δ t} = - kA \frac{Δ T}{Δ x} ,$$

where
Δt is the time interval during which the amount of heat
A is the cross-sectional surface area,
ΔT is the temperature difference between the ends,
Δx is the distance between the ends.
k is thermal conductivity of support pad material
Q is the heat that flows through the support pad

To minimize heat transfer, the contact area A between the support pad and the substrate should be small, the thermal conductivity k of the support pad material should be low, and the length of heat transfer path Δx (e.g., the length of the support pad) should be large. Example materials having relatively low thermal conductivity values include alumina (about 25 W/mK), yttria-stabilized zirconia (about 3 W/mK), and quartz (about 1.5 W/mK).

In tests, it has been observed that quartz support pads and zirconia support pads have significantly less effect on substrate temperature (e.g., they do not produce significant cold spots on substrates) than aluminum support pads and even alumina support pads.

In addition to having a low thermal conductivity, zirconia has comparatively good mechanical strength. The high flexural strength of zirconia enables fabrication of small cross-section support pads, which reduces the contact area between the substrate and the support pad. Further, the high hardness of zirconia allows a relatively small contact area, A, between the support pad and the substrate. Because the mechanical properties of zirconia compare favorably with those of quartz, support pads fabricated with zirconia can provide lower thermal conduction than those fabricated with quartz.

Further, because zirconia is relatively chemically inert (at least in comparison to some other materials such as quartz), it can provide long-lived, dimensionally stable support pads even in aggressive environments. In some tests, zirconia was found to be thousands of times more resistant to vapor etch than quartz.

However, support pads fabricated from quartz may still be suitable as a support pad material. Quartz has very low heat conductivity, and hence enables comparable thermal performance to zirconia. While quartz is more likely to be etched in some environments, it can still be used in support pads in such environments, so long as the quartz support pads are treated as consumable parts.

In certain embodiments, a zirconia or quartz support pad has contact surface with the substrate and a finger that extends from the contact surface to a ring or other attachment structure to which the fingers are attached. As examples, the finger shape may be generally rod-shaped, generally rectangular-shaped, or generally triangular-shaped. In some embodiments, the shape may be configured as a thermal choke.

In certain embodiments, fingers of zirconia or quartz support pads have a length (distance between the contact surface and the attachment structure of at least about 10 mm or at least about 15 mm. In some embodiments, the distance is about 18 to 25 mm.

In certain embodiments, a contact surface of a zirconia or quartz support pad has a contact area with a substrate that is no greater than about 10 mm² or no greater than about 5 mm².

In some embodiments, the apparatuses described herein may include a controller that is configured to control various aspects of the apparatus in order to perform the techniques described herein. For example, referring back to FIG. 1, apparatus 100 includes a controller 131 (which may include one or more physical or logical controllers) that is communicatively connected with and that controls some or all of the operations of a processing chamber. The system controller 131 may include one or more memory devices 133 and one or more processors 135. In some embodiments, the apparatus includes a switching system for controlling flow rates and durations, the substrate heating unit, the substrate cooling unit, the loading and unloading of a substrate in the chamber, the thermal floating of the substrate, and the process gas unit, for instance, when disclosed embodiments are performed. In some embodiments, the apparatus may have a switching time of up to about 500 ms, or up to about 750 ms. Switching time may depend on the flow chemistry, recipe chosen, reactor architecture, and other factors.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

In some embodiments, the apparatus may further be configured to generate a plasma and use the plasma for some processing in various embodiments. This may include having a plasma source configured to generate a plasma within the chamber interior, such as a capacitively coupled plasma (CCP), an inductively coupled plasma (ICP), an upper remote plasma, and a lower remote plasma.

The apparatuses described herein may be used for various etching techniques including, but not limited to, continuous etching methods and cyclic methods such as atomic layer etching.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. An apparatus for semiconductor processing, the apparatus comprising:
a processing chamber including chamber walls that at least partially bound a chamber interior, and a chamber heater configured to heat the chamber walls; and
a pedestal positioned within the chamber interior and including:
a substrate heater having a plurality of light emitting diodes (LEDs),
a window positioned above the substrate heater comprising a material transparent to light from the LEDs, wherein the window comprises sapphire, spinel, AlON, IR grade fused silica, or a fluoride of an alkaline earth element, and
three or more substrate support pads, each substrate support pad having a substrate support surface vertically offset from the window and configured to support a substrate such that the window and the substrate supported by the three or more substrate support pads are offset by a nonzero distance.

2. The apparatus of claim 1, wherein the window has thickness of about 5 to 40 mm.

3. The apparatus of claim 1, wherein the window has a diameter of about 250-500 mm.

4. The apparatus of claim 1, wherein a top surface of the window is nonplanar, and/or a bottom surface of the window is nonplanar.

5. The apparatus of claim 1, wherein:
the pedestal further includes a sidewall, and
an outer region of the window is thermally connected to the sidewall such that heat can be transferred between the outer region and the sidewall.

6. The apparatus of claim 1, wherein:
the pedestal includes a bowl in which the substrate heater is positioned,
the bowl includes one or more sidewalls having an exterior surface that comprises reflective material.

7. The apparatus of claim 1, wherein the pedestal further comprises a pedestal cooler that:
is thermally connected to the LEDs such that heat can be transferred between the LEDs and the pedestal cooler,
includes at least one fluid channel within the pedestal, and
is configured to flow a cooling fluid within the at least one fluid channel.

8. The apparatus of claim 7, wherein the pedestal further includes a pedestal heater configured to heat one or more exterior surfaces of the pedestal.

9. The apparatus of claim 1, wherein:
a first set of LEDs are arranged in a first circle having a first radius around a center axis of the substrate heater, and equally spaced apart from each other, and
a second set of LEDs are arranged in a second circle having a second radius larger than the first radius around the center axis, and equally spaced apart from each other.

10. The apparatus of claim 1, wherein:
a first set of LEDs are electrically connected to form a first electrical zone,
a second set of LEDs are electrically connected to form a second electrical zone, and
the first and second electrical zones are independently controllable.

11. The apparatus of claim 1, further comprising a pyrometer having a detector, wherein:
the detector is connected to a port and sensor window through a fiberoptic cable.

12. The apparatus of claim 11, wherein the pyrometer is configured to detect emissions having one or more wavelengths of about 1 to about 4 microns.

13. The apparatus of claim 1, further comprising:
a gas distribution unit including:
one or more fluid inlets, and
a faceplate having a plurality of through-holes fluidically connected to the one or more fluid inlets and to the chamber interior, and having a front surface partially bounding the chamber interior; and
a unit heater thermally connected to the faceplate such that heat can be transferred between the faceplate and the unit heater.

14. The apparatus of claim 1, wherein the window comprises sapphire.

15. A method comprising:
supporting a substrate in a processing chamber having chamber walls using a pedestal having a plurality of substrate support pads that each contact an edge region of the substrate;
heating, while the substrate is supported by only the plurality of substrate supports, the substrate to a first temperature by emitting visible light from a plurality of light emitting diodes (LEDs) under the substrate through a window comprising sapphire, spinel, AlON, IR grade fused silica, or a fluoride of an alkaline earth element; and
etching, while the substrate is supported by only the plurality of substrate supports and while the substrate is at the first temperature, a surface of the substrate.

16. An apparatus for semiconductor processing, the apparatus comprising:
a processing chamber including chamber walls that at least partially bound a chamber interior, and a chamber heater configured to heat the chamber walls; and
a pedestal positioned within the chamber interior and including:
a substrate heater having a plurality of light emitting diodes (LEDs),
a window positioned above the substrate heater comprising a material transparent to light from the LEDs, and
three or more substrate support pads, each substrate support pad having a substrate support surface vertically offset from the window and configured to support a substrate such that the window and the substrate supported by the three or more substrate support pads are offset by a nonzero distance, wherein the substrate support pads comprise zirconia or quartz.

17. The apparatus of claim 16, wherein each substrate support comprises a zirconia.

18. The apparatus of claim 16, wherein each substrate support includes a temperature sensor configured to detect a temperature of a substrate positioned on the substrate support surface.

19. The apparatus of claim 16, wherein a top surface of the window is nonplanar, and/or a bottom surface of the window is nonplanar.

20. The apparatus of claim 16, wherein:
the pedestal further includes a sidewall, and
an outer region of the window is thermally connected to the sidewall such that heat can be transferred between the outer region and the sidewall.

21. The apparatus of claim 16, wherein:
the pedestal includes a bowl in which the substrate heater is positioned,
the bowl includes one or more sidewalls having an exterior surface that comprises reflective material.

22. The apparatus of claim 16, wherein the pedestal further comprises a pedestal cooler that:
is thermally connected to the LEDs such that heat can be transferred between the LEDs and the pedestal cooler,
includes at least one fluid channel within the pedestal, and
is configured to flow a cooling fluid within the at least one fluid channel.

23. The apparatus of claim 22, wherein the pedestal further includes a pedestal heater configured to heat one or more exterior surfaces of the pedestal.

24. The apparatus of claim 16, wherein:
a first set of LEDs are arranged in a first circle having a first radius around a center axis of the substrate heater, and equally spaced apart from each other, and
a second set of LEDs are arranged in a second circle having a second radius larger than the first radius around the center axis, and equally spaced apart from each other.

25. The apparatus of claim 16, wherein:
a first set of LEDs are electrically connected to form a first electrical zone,
a second set of LEDs are electrically connected to form a second electrical zone, and
the first and second electrical zones are independently controllable.

26. The apparatus of claim 16, further comprising a pyrometer having a detector, wherein:
the detector is connected to a port and sensor window through a fiberoptic cable.

27. The apparatus of claim 26, wherein the pyrometer is configured to detect emissions having one or more wavelengths of about 1 to about 4 microns.

28. The apparatus of claim 16, further comprising:
a gas distribution unit including:
one or more fluid inlets, and
a faceplate having a plurality of through-holes fluidically connected to the one or more fluid inlets and to the chamber interior, and having a front surface partially bounding the chamber interior; and
a unit heater thermally connected to the faceplate such that heat can be transferred between the faceplate and the unit heater.

29. The apparatus of claim 16, wherein the substrate support pads comprise yttria-stabilized zirconia.

30. A method comprising:
supporting a substrate in a processing chamber having chamber walls using only a pedestal having a plurality of substrate support pads that each contact an edge region of the substrate, wherein the substrate support pads comprise zirconia or quartz;
heating, while the substrate is supported by only the plurality of substrate supports, the substrate to a first temperature by emitting visible light from a plurality of light emitting diodes (LEDs) under the substrate; and
etching, while the substrate is supported by only the plurality of substrate supports and while the substrate is at the first temperature, a surface of the substrate.
